(19) United States
(12) Patent Application Publication
(10) Pub. No.: US 2006/0157450 A1
(43) Pub. Date: Jul. 20, 2006

(54) METHOD FOR IMPROVING HSS CMP PERFORMANCE

(76) Inventors: Hsin-Kun CHU, Hsin-Chu County (TW); Teng-Chun Tsai, Hsin-Chu City (TW); Kai-Gin Yang, Tainan County (TW); Chihyueh Lee, Tainan County (TW)

Correspondence Address: NORTH AMERICA INTELLECTUAL PROPERTY CORPORATION, P.O. BOX 506, MERRIFIELD, VA, 22116, US

(21) Appl. No.: 10/905,761

(22) Filed: Jan. 20, 2005

(51) Int. Cl. C03C 15/00; H01L 21/302; C23F 1/00; B44C 1/22

(52) U.S. Cl. 216/88; 438/692; 216/89

(57) ABSTRACT

Disclosed is a method for improving HSS CMP performance. After performing a HSS CMP process for a predetermined time, DI water is introduced and the polishing process is continued, so that the CMP rate and performance can be improved.

### BACKGROUND OF INVENTION

1. Field of the Invention

The present invention relates to a method for improving high selective slurry (HSS) chemical-mechanical polishing (CMP) performance, and more particularly, to a method of adding deionized water in a CMP process for improving the overall HSS CMP performance.

2. Description of the Prior Art

In the semiconductor industry, chemical mechanical polishing (CMP) is the most common and important planarization tool applied. For example, the CMP process can be used to remove a topographical target of a thin film layer on a semiconductor wafer and to produce a wafer with both a regular and planar surface. In a CMP process, slurry is provided in a surface subject to planarization, and a mechanical polishing process is performed on the surface of the wafer. The slurry includes chemical agents and abrasives. The chemical agents may be PH buffers, oxidants, surfactants or the like, and the abrasives may be silica, alumina, zirconium oxide, or the like. The chemical reactions evoked by the chemical agents and the abrasion between the wafer, the abrasives, and the polishing pad can planarize the surface of the wafer.

In recent history, CMP processes have been widely adopted in shallow trench isolation (STI) processes. Please refer to FIG. 1 to FIG. 3. FIG. 1 to FIG. 3 are perspective diagrams showing a shallow trench isolation fabrication according to the prior art. As shown in FIG. 1, a pad oxide layer 12 and silicon nitride (Si₃N₄) layer 14 are disposed on a substrate 10, in which the substrate 10 further comprises a shallow trench 16 and a silicon dioxide (SiO₂) layer 18. The silicon dioxide layer 18, being served as a dielectric layer, is formed by a process such as a chemical vapor deposition (CVD) process. Next, a CMP process is performed on the silicon dioxide layer 18 outside the shallow trench 16, in which the CMP process is stopped at the silicon nitride layer 14, as shown in FIG. 2. The silicon nitride layer 14 and the pad oxide layer 12 are then removed and under an ideal condition, a height differential ΔD can be observed between the silicon dioxide layer 18 inside the shallow trench 16 and the active region of the substrate surface in proximity. If the CMP process is able to planarize and remove the silicon dioxide layer 18 outside the shallow trench 16 evenly and stop the process at the silicon nitride layer 14, a positive height differential ΔD can be obtained. Hence, the silicon dioxide layer 18 inside the shallow trench 18 is higher than the substrate surface of the active region and thereby effectively reduces electrical leakage.

In order to obtain a positive height differential ΔD, the planarization and the polishing endpoint has always been a challenge in CMP processes. In general, the determination is based on various factors including the characteristics (compactness) of the silicon dioxide layer, the uniformity of the silicon dioxide surface, the composition and pH value of the slurry, the polishing pad composition, the platen rotation speed, and the head down force of the wafer head.

In STI processes, in order to completely remove the silicon dioxide layer 18 outside the shallow trench 16 and prevent an over etching of the silicon nitride layer 14 thereby damaging the active region devices, the selectivity ratio between the silicon dioxide and the silicon nitride should be increased. In the past, a solution used by most industries is to replace the traditional silica abrasive alkaline solution with high selectivity slurry (HSS) for performing CMP processes. Recently, the HSS has been widely applied in STI CMP processes of 0.13 um technology node and beyond for fabricating devices with higher reliability.

Despite the fact that traditional oxide slurry STI CMP processes can easily reach a polishing rate of over 3000 A/min, the polishing rate for STI CMP processes by using HSS however is significantly slower. Please refer to FIG. 4. FIG. 4 is a curve diagram showing the relationship between the polishing rate and polishing time of a STI CMP process by using HSS according to the prior art. As shown in FIG. 4, the polishing rate of the process decreases as the polishing time increases and consequently, it becomes virtually impossible for the process to reach a polishing rate of 1500 A/min. Moreover, HSS STIP CMP processes may also cause numerous problems including slurry residues, SiO₂ residues on the Si₃N₄ layer, microscratches on the surface of the wafer, and thickness limitation of the SiO₂ layer, and therefore the process window will be limited.

According to U.S. Pat. No. 6,132,294, a method for improving CMP process by allowing the wafer to detach easily from the polishing pad thereby preventing damages or microscratches is disclosed. According to the method, the CMP process is first performed by using traditional slurry comprised of silicon dioxide or aluminum oxide. After the end of the CMP process, the injection of slurry is stopped and water is injected into the process instead. At the same time, the rotation speed of the polishing pad is also increased for allowing the wafer to successfully detach from the polishing pad. Nevertheless, information regarding to HSS CMP processes has not been stated according to this patent, and the influence of HSS on slow polishing rate in STI processes was also unaddressed. Hence, the improvement of HSS in the speed, performance of CMP processes, and process window has always been a challenge.

### SUMMARY OF INVENTION

It is therefore an objective of the present invention to provide a method for improving HSS CMP performance and solving the above-mentioned problems by introducing a deionized water polishing step in the later stage of each CMP process.

According to the present invention, a method for improving HSS CMP performance comprises: providing a polishing pad and a wafer head, wherein the wafer head carries a wafer; applying a high selectivity slurry on the polishing pad and applying a head down force to the wafer head for performing a chemical mechanical polishing process by contacting the wafer to the polishing pad, wherein the polishing pad and the wafer head each include a polishing pad speed and a wafer head speed; and applying deionized water to the polishing pad for continuing with the CMP process.

By introducing deionized water in the later stage of each CMP process, the method is able to effectively dilute the concentration of the HSS, increase the overall polishing rate of the CMP process, and at the same time, reduce microscratch damage on the wafer and improve defect control.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 to FIG. 3 are perspective diagrams showing a shallow trench isolation fabrication according to the prior art.

FIG. 4 is a curve diagram showing the relationship between the polishing rate and polish time of a HSS STI CMP process by using a HSS according to the prior art.

FIG. 5 to FIG. 9 are perspective diagrams showing a method for improving HSS CMP performance according to the present invention.

FIG. 10 is a curve diagram showing the relationship between the removal rate of the silicon dioxide layer and the polishing time after deionized water is added according to the present invention.

FIG. 11 is a curve diagram showing the relationship between the removal rate of the silicon nitride and the polishing time after deionized water is added.

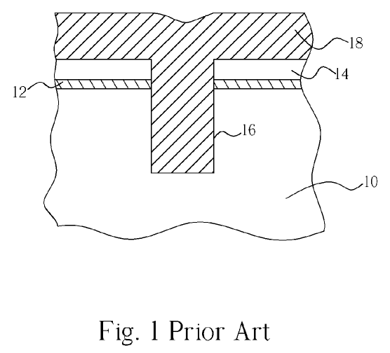

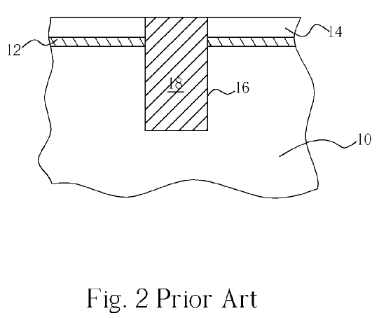

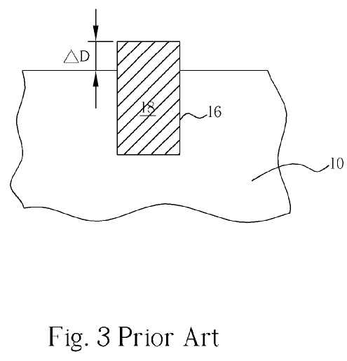

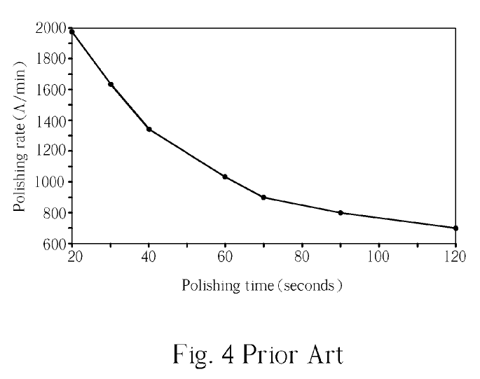

### DETAILED DESCRIPTION

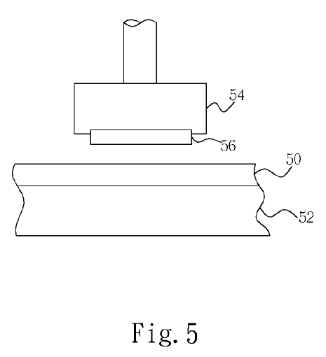

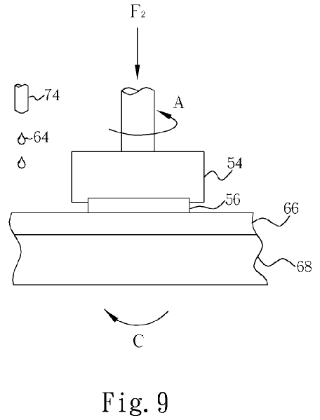

Please refer to FIG. 5 to FIG. 9. FIG. 5 to FIG. 9 are perspective diagrams showing a method for improving HSS CMP performance according to the present invention. According to the preferred embodiment of the present invention, the CMP process is utilized in a STI fabrication process for removing the silicon dioxide layer outside the shallow trench. As shown in FIG. 5, a first polishing pad 50 is disposed on a first polishing platen 52 and a wafer head 54 is utilized for fixing a wafer 56 in place. Preferably, the wafer 56 is a semiconductor wafer comprising integrated circuits or other semiconductor devices. The wafer 56 is fixed in a detachable manner on the wafer head 54.

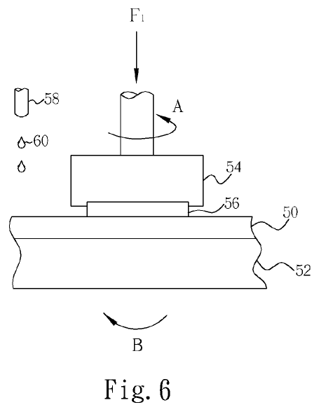

As shown in FIG. 6, a head down force F₁ is applied to the wafer head 54 for contacting the wafer 56 to the first polishing pad 50 disposed on the first polishing platen 52. A first CMP process is then performed by injecting a first HSS 60 to the first polishing pad 50 via a slurry feed 58. During the first CMP process, each of the wafer head 54 and the first polishing pad 50 generates a wafer head speed and a first polishing pad speed that rotates in separate directions according to an arrow A and an arrow B.

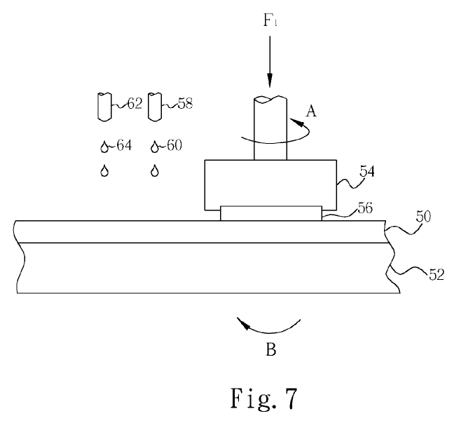

As shown in FIG. 7, after the first CMP process is performed for a predetermined time, another water feed 62 is used for providing deionized water 64 to the first polishing pad 50. Preferably, the first CMP process is continued for another 5-60 seconds before being stopped completely. The stopping of the first CMP process will then detach the wafer 56 from the first polishing pad 50. Due to the fact that an increase in the wafer head speed and the first polishing pad speed will result in a decrease in the overall polishing rate, the wafer head speed and the first polishing pad speed of the present method are maintained at constant speeds during the first CMP process when the deionized water 64 is injected to ensure that the polishing rate of the first CMP process can be constantly increased.

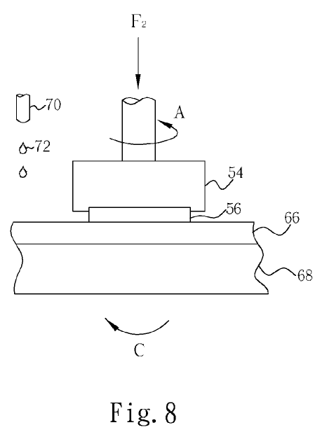

As shown in FIG. 8, a second polishing pad 66 is disposed on a second polishing platen 68 for starting a second CMP process. Alternatively, the second polishing pad 66 can be replaced by the first polishing pad 50 by first removing the wafer 56 from the surface of the first polishing pad 50 by using the wafer head 54, cleaning the first polishing pad 50 by using a conditioner and deionized water, and replacing the clean first polishing pad 50 as the pad used in the second CMP process. In the second CMP process, a head down force F₂ is first applied to the wafer head 54 for contacting the wafer 56 to the second polishing pad 66 and at the same time, a second HSS 72 is injected to the second polishing pad 66 via a slurry feed 70. Consequently, a polishing process is performed on the wafer 56 by using the wafer head 54 to generate a wafer head speed toward a direction A and using the second polishing pad 66 to generate a second polishing pad speed toward a direction C.

Next, the injection of the second HSS 72 is stopped after the second CMP process has been performed for a predetermined time, such as 50-80 seconds. After the injection of the second HSS 72 is stopped, the second CMP process is continued for another 5-60 seconds while injecting the deionized water 64 via a water feed 74 before reaching a complete stop.

According to the present invention, the first high selectivity slurry 60 and the second high selectivity slurry 72 is a ceric-base slurry or a zirconic-base slurry, in which the slurry may contain materials such as ceria (CeO₂) or zirconia (ZrO₂).

In addition, the head down force F₁ or F₂ of the wafer head can be selectively decreased during the first or second CMP process according to fabrication demand. Moreover, a third or fourth polishing pad can also be provided to perform a third or fourth CMP process. In order to increase the polishing rate of the HSS, deionized water can be injected in the end stage of every CMP process to dilute the concentrate of the HSS for improving the overall CMP rate and performance.

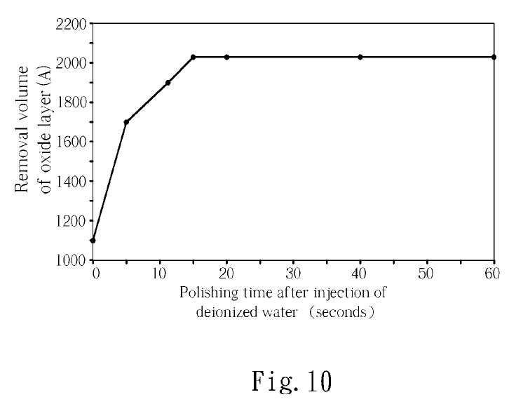

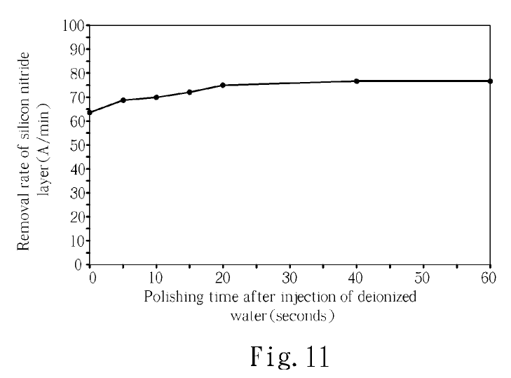

By injecting deionized water (despite whether HSS is continuously injected or not) in the end of each HSS STI CMP process, the present invention provides a method that is able to dilute and decrease the adhesiveness of HSS and reduce the amount of excess slurry remains, thereby increasing the overall polishing performance and preventing microscratches on the wafer surface. Please refer to FIG. 10 and FIG. 11. FIG. 10 is a curve diagram showing the relationship between the removal rate of the silicon dioxide layer and the polishing time after deionized water is added whereas FIG. 11 is a curve diagram showing the relationship between the removal rate of the silicon nitride and the polishing time after deionized water is added. As shown in FIG. 10, the removal rate of the silicon dioxide layer increases rapidly after the addition of deionized water for approximately 10 seconds, indicating that the present invention is capable of effectively increasing the speed of the HSS STI CMP process. As shown in FIG. 11, the removal rate of the silicon nitride did not increase significantly after the addition of deionized water, hence the selectivity ratio between silicon dioxide and silicon nitride in the CMP process can be well maintained.

In contrast to the prior art, the present invention discloses a method by adding deionized water in the later stage of each HSS CMP process. After the deionized water is added, the choice of adding additional HSS can be further decided according to the actual polishing requirement. By using the present method, the polishing rate of the CMP process to the oxide layer can be greatly increased, which will in turn increase the selectivity ratio between silicon dioxide and silicon nitride. Moreover, the present invention also provides a solution for improving slurry residues, microscratches on wafer surface, process window limitations, and the overall performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for improving high selectivity slurry (HSS) chemical mechanical polish (CMP) performance, the method comprising:
providing a polishing pad and a wafer head, wherein the wafer head carries a wafer;
applying a high selectivity slurry on the polishing pad and applying a head down force to the wafer head for performing a chemical mechanical polishing process by contacting the wafer to the polishing pad, wherein the polishing pad and the wafer head each include a polishing pad speed and a wafer head speed; and
applying deionized water to the polishing pad for continuing with the CMP process.

2. The method of claim 1 further comprising:
stopping the application of the high selectivity slurry to the polishing pad before the deionized water is applied to the polishing pad.

3. The method of claim 1, wherein the high selectivity slurry is continuously applied to the polishing pad when the deionized water is applied to the polishing pad.

4. The method of claim 1, wherein the polishing pad speed and the wafer head speed are maintained at constant speeds when the deionized water is applied to the polishing pad.

5. The method of claim 1, wherein the head down force is maintained at a constant force when the deionized water is applied to the polishing pad.

6. The method of claim 1, wherein the head down force is decreased at the same time when the deionized water is applied to the polishing pad.

7. The method of claim 1, wherein the chemical mechanical polishing process is continued for an additional 5-60 seconds after the deionized water is applied.

8. The method of claim 1, wherein the high selectivity slurry is a ceric-base slurry or a zirconic-base slurry.

9. The method of claim 1, wherein the high selectivity slurry contains ceria (CeO₂) or zirconia (ZrO₂).

10. The method of claim 1, wherein the chemical mechanical polishing process is applied to a shallow trench isolation (STI) process.

11. A method for improving high selectivity slurry (HSS) chemical mechanical polish (CMP) performance, the method comprising:
utilizing a first polishing pad and a wafer head for performing a first chemical mechanical polishing process on a wafer, wherein a first high selectivity slurry is injected during the first chemical mechanical polishing process;
injecting deionized water during the later stage of the first chemical mechanical polishing process for diluting the first high selectivity slurry;
stopping the first chemical mechanical polishing process;
utilizing a second polishing pad for performing a second chemical mechanical polishing process, wherein a second high selectivity slurry is injected during the second chemical mechanical polishing process; and
injecting deionized water during the later stage of the second chemical mechanical polishing process for diluting the second high selectivity slurry.

12. The method of claim 11, wherein the injection of the first high selectivity slurry is ceased when the first high selectivity slurry is diluted by the deionized water.

13. The method of claim 11, wherein the injection of the first high selectivity slurry is continued when the first high selectivity slurry is diluted by the deionized water.

14. The method of claim 11, wherein the injection of the second high selectivity slurry is ceased when the second high selectivity slurry is diluted by the deionized water.

15. The method of claim 11, wherein the second high selectivity slurry is continuously injected when the second high selectivity slurry is diluted by the deionized water.

16. The method of claim 11, wherein the first polishing pad speed or the second polishing pad speed of the first and the second chemical mechanical polishing process, and the wafer head speed are maintained at constant speeds after the deionized water is applied.

17. The method of claim 11, wherein the wafer head is applied with a head down force, and the head down force is maintained at a constant force when the deionized water is applied to the first polishing pad or the second polishing pad.

18. The method of claim 11, wherein the wafer head is applied with a head down force, and the head down force is decreased at the same time when the deionized water is applied to the first polishing pad or the second polishing pad.

19. The method of claim 11, wherein the first chemical mechanical polishing process or the second chemical mechanical polishing process is continued for an additional 5-60 seconds after the deionized water is applied.

20. The method of claim 11, wherein the first high selectivity slurry or the second high selectivity slurry is a ceric-base slurry or a zirconic-base slurry.

21. The method of claim 11, wherein the first high selectivity slurry or the second high selectivity slurry contain ceria (CeO₂) or zirconia (ZrO₂).

22. The method of claim 11, wherein the chemical mechanical polishing process is applied to a shallow trench isolation (STI) process.
